(19) United States
(12) Patent Application Publication
(10) Pub. No.: US 2025/0300062 A1
(43) Pub. Date: Sep. 25, 2025

(54) INTEGRATED CIRCUIT PACKAGE COMPRISING HOLLOW FILLER-BASED BUILD-UP MATERIAL

(71) Applicant: Intel Corporation, Santa Clara, CA (US)

(72) Inventors: Jieying Kong, Chandler, AZ (US); Dilan Seneviratne, Phoenix, AZ (US); Gang Duan, Chandler, AZ (US); Shuqi Lai, Phoenix, AZ (US); Peumie Abeyratne Kuragama, Chandler, AZ (US); Srinivas Venkata Ramanuja Pietambaram, Chandler, AZ (US)

(73) Assignee: Intel Corporation, Santa Clara, CA (US)

(21) Appl. No.: 18/614,334

(22) Filed: Mar. 22, 2024

(51) Int. Cl. H01L 23/498; H01L 23/00; H01L 23/538; H01L 25/065

(52) U.S. Cl. CPC H01L 23/49894; H01L 23/49822; H01L 23/5384; H01L 25/0655; H01L 24/16; H01L 2224/16227; H01L 2924/1432; H01L 2924/1517

(57) ABSTRACT

An apparatus comprising an integrated circuit package comprising a package substrate comprising an interconnect layer; and at least one dielectric material comprising hollow fillers, the at least one dielectric material in contact with at least a portion of a top side of the interconnect layer and at least a portion of a bottom side of the interconnect layer.

### BACKGROUND

A package substrate may be used in an electronic device to provide electrical and mechanical support to integrated circuit components coupled thereto. A package substrate may host a network of conductive traces that connect various components on the surface of the package substrate. The package substrate may also feature conductive pathways (e.g., vias) that traverse the layers of the substrate, enabling connections between different layers of the package substrate. A package substrate may provide electrical connection between one or more integrated circuit components and various circuits of a printed circuit board upon which the package substrate is mounted.

### BRIEF DESCRIPTION OF THE DRAWINGS

FIG. 1 illustrates a package comprising a package substrate with at least one hollow filler-based build-up material and an embedded bridge die providing power delivery, in accordance with any of the embodiments disclosed herein.

FIG. 2 illustrates another package comprising a package substrate with at least one hollow filler-based build-up material and an embedded bridge die providing power delivery, in accordance with any of the embodiments disclosed herein.

FIG. 3 illustrates a package comprising a package substrate with hollow filler-based build-up materials and solid filler based build-up materials, in accordance with certain embodiments.

FIG. 4 illustrates a package comprising a package substrate with hollow filler-based build-up materials and solid filler based build-up materials, in accordance with certain embodiments.

FIG. 5 provides a schematic illustration of a cross-sectional view of an example integrated circuit device, in accordance with any of the embodiments disclosed herein.

FIG. 6 is a top view of a wafer and dies that may be included in a microelectronic assembly, in accordance with any of the embodiments disclosed herein.

FIG. 7 is a cross-sectional side view of an integrated circuit device that may be included in a microelectronic assembly, in accordance with any of the embodiments disclosed herein.

FIGS. 8A-8D are perspective views of example planar, FinFET, gate-all-around, and stacked gate-all-around transistors.

FIG. 9 is a cross-sectional side view of an integrated circuit device assembly that may include a microelectronic assembly, in accordance with any of the embodiments disclosed herein.

FIG. 10 is a block diagram of an example electrical device that may include a microelectronic assembly, in accordance with any of the embodiments disclosed herein.

### DETAILED DESCRIPTION

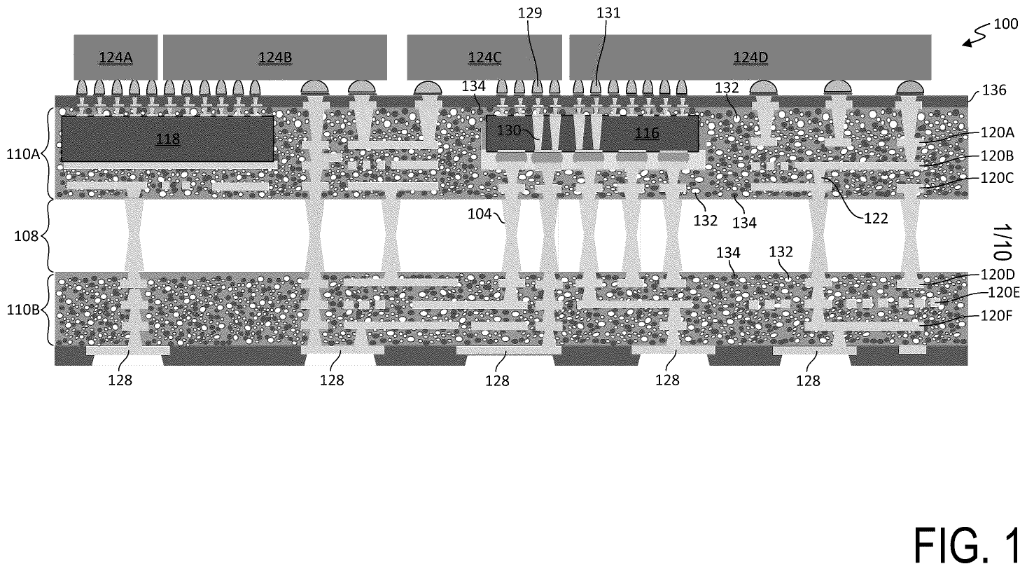

FIG. 1 illustrates a package 100 comprising a package substrate with hollow filler-based build-up materials and an embedded bridge die 116 providing power delivery, in accordance with any of the embodiments disclosed herein. The package substrate may comprise a core layer 108, a first outer portion 110A above the core layer 108, and a second outer portion 110B below the core layer 108. The first outer portion 110A and/or the second outer portion 110B may comprise a plurality of build-up layers including at least one layer comprising a hollow filler-based build-up material. In the depicted embodiment, the embedded bridge die 116 is embedded within the first outer portion 110A.

In various embodiments, a package 100 may be suitable to provide enhanced power delivery and high-speed input/output (HSIO) capabilities to one or more integrated circuit dies 124 through one or more embedded bridge dies 116 and hollow filler-based build-up materials as described herein. An embedded bridge die 116 may facilitate achievement of a power delivery target, based at least in part on through via connections 130 (also referred to as power vias) of the embedded bridge die that deliver power from the bottom side of the embedded bridge die to the top side of the embedded bridge die. The power connections may then be coupled from the top side of the embedded bridge die to one or more of conductive contacts 129 and/or 131 on the top side of the package 100 (for connection to one or more integrated circuit dies 124).

A hollow filler-based build-up material may have a low dissipation factor (Df) and a low dielectric constant (Dk), where Df refers to the imaginary part of the dielectric constant and Dk refers to the real part of the dielectric constant (in other words, the refractive index). Df may reflect a material's ability to dissipate electrical energy while Dk may reflect the material's ability to store electrical energy. Such a material with a low Df and Dk may facilitate high speed signaling by traces embedded in the package 100 (e.g., HSIO lines that couple signals from integrated circuit dies 124 coupled to the top of the package 100 to conductive contacts on the bottom of the package 100, which may be coupled to circuits, integrated circuit dies, or other electronic devices on or coupled to the same printed circuit board as the package) due to low insertion loss.

In some embodiments, all of the dielectric layers of the build-up layers of the first outer portion 110A and/or second outer portion 110B may comprise hollow fillers, while in other embodiments, only a subset of the dielectric layers comprise hollow fillers. In particular embodiments, one or more dielectric layers that comprise hollow fillers may also comprise solid fillers as well. In some embodiments, one or more dielectric layers that do not comprise hollow fillers may comprise solid fillers.

In various embodiments, the package 100 may comprise one or more embedded bridge dies 116 that include through via connections for power as well as one or more embedded bridge dies 118 that do not include through via connections for power (e.g., such bridge dies may merely couple signals from different integrated circuit dies together).

Various embodiments may provide one or more advantages, such as efficient delivery of power from a package to one or more integrated circuit dies coupled to the package, reduced insertion loss for HSIO lines in a package, and improved HSIO line performance (e.g., speed, power, etc.).

The package 100 may be a multi-die integrated circuit package comprising a package substrate with hollow filler-based build-up materials and an embedded bridge die 116. The package 100 includes a core layer 108 and vias 104 through the core layer 108. The core layer 108 may comprise any suitable dielectric material that may provide structural support. For example, the core layer 108 may comprise one or more of glass, a resin material (e.g., bismaleimide triazine), a fiberglass weave, a ceramic material, an epoxy-based laminate material reinforced with glass fibers, silicon, a laminate (e.g., a polyimide), a ceramic material, an organic polymer, and one or more fillers (e.g., silicon dioxide, glass beads, silica particle fillers).

A first outer portion 110A and second outer portion 110B comprising build-up layers are formed respectively on the top and bottom sides of the core layer 108, with the first outer portion 110A on the top side of the core layer 108 and the second outer portion 110B on the bottom side of the core layer 108. The build-up layers may comprise alternating conductive layers and insulating layers, where a conductive layer may have any number of different (e.g., electrically isolated) interconnects on the same plane of the package substrate. In some embodiments, a conductive layer may comprise patterned metal (e.g., copper, aluminum, tungsten, gold, etc.) forming signal (e.g., an HSIO signal) or power/ground plane layers and may be bordered by one or more dielectric materials (e.g., hollow filler-based build-up materials or other dielectric materials) to electrically isolate the patterned metal. For example, the build-up layers may include metal traces 120A-F in metallization layers and pillars 122 between the metallization layers as shown to electrically couple components on the top of the package 100 with conductive contacts 128 (e.g., pads) at the bottom of the package. For example, the build-up layers may provide connections between IC dies 124 (e.g., 124A-D) coupled to the top side of the package and components (e.g., circuits, IC dies, or other electronic devices) coupled to a circuit board (e.g., a motherboard, main board, etc.) via the conductive contacts 128 at the bottom of the package.

Thus, one side of the package substrate may interface with one or more IC dies 124. For example, the top side of the package substrate may include conductive contacts (e.g., solder pads) that couple to conductive contacts of the IC dies 124 (e.g., via a solder connection, not shown). Another side of the package substrate (e.g., a bottom side) that is opposite to the first side may interface with a circuit board, other integrated circuit dies, and/or passive component structures. For example, solder balls may be formed on the conductive contacts 128 and used to couple the conductive contacts 128 of the package 100 to corresponding conductive contacts of a circuit board and/or other components. A conductive contact may comprise any suitable conductive material (e.g., copper) arranged in any suitable shape.

The package 100 also includes at least one embedded bridge die 116 with power vias 130 (e.g., through silicon vias) from the top of the embedded bridge die to the bottom of the embedded bridge die. In general, the embedded bridge die 116 may provide die-to-die interconnect while managing power delivery efficiency. The embedded bridge die 116 may be embedded within the build-up layers of the first outer portion 110A and may electrically couple IC dies together (e.g., IC die 124C with IC die 124D). An embedded bridge die 116 may comprise a die with conductive material (e.g., a plurality of metal layers, not explicitly shown) to provide connections between conductive contacts (e.g., pads) of two or more IC dies 124. The embedded bridge die 116 may include any suitable passive and/or active components to interconnect IC dies (e.g., 124C and 124D). As depicted, bridge die 116 includes power vias 130 to connect a top side of the bridge die 116 with a bottom side of the bridge die 116. In various embodiments, the power vias 130 may carry power signals (e.g., between conductive contacts 128 and conductive contacts 129 and 131 to connect to IC dies 124C and 124D). The power vias 130 may have conductive contacts on a top side and a bottom side to allow for power delivery through the embedded bridge die 116 to the integrated circuit dies (e.g., 124C, 124D) coupled to the embedded bridge die. In some embodiments, the embedded bridge die may be an Intel® embedded multi-die interconnect bridge with through silicon vias (EMIB-T).

In some embodiments, one or more bridge dies 118 without power vias may be embedded within the first outer portion 110A. In one embodiment, a bridge die 118 is an embedded multi-die interconnect bridge (EMIB). A bridge die 118 may include any suitable characteristics of a bridge die 116, but does not include power vias 130 extending from a top side to a bottom side. In various embodiments, an embedded bridge die 116 or 118 comprises a small silicon die embedded in the package substrate under the edges of the dies the respective bridge die couples together.

In various embodiments, any one or more of the build-up layers of the first outer portion 110A and/or second outer portion 110B may include a hollow filler based material. In the embodiment depicted, the dielectric layers of the build-up layers of both portions 110A and 110B all include a hollow filler based material. A hollow filler based material is characterized in that the material includes a plurality of hollow fillers 132 (shown as white areas) that each form a void within an otherwise solid material.

The solid material of the hollow filler based material may comprise any suitable dielectric material comprising one or more polymers such as a resin (e.g., an epoxy resin), an inorganic dielectric (e.g., silicon dioxide, aluminum oxide, silicon nitride, etc.), or other suitable dielectric material. In some instances, a hollow filler based material may additionally comprise one or more solid filler materials (e.g., solid fillers 134) and/or additives. For example, a solid filler material may comprise a silica based material (e.g., silicon oxide beads). In some instances, a hollow filler-based build-up material may comprise an Ajinomoto Build-up Film.

Thus, any of the dielectric build-up layers of the first outer portion 110A and/or second outer portion 110B may comprise embedded hollow fillers, solid fillers, additives, and/or polymer based materials (e.g., resins). The composition of different build-up layers may vary. For example, some build-up layers may omit hollow fillers, solid fillers, and/or additives.

A hollow filler-based buildup material may have material characteristics suitable for its placement in a build-up layer. For example, a hollow filler-based buildup material (e.g., that is placed adjacent to an HSIO line) may have a relatively low Dk and/or Df value. For example, the average Dk value in a layer of the hollow filler-based build-up material may be between 2 and 2.5 (whereas a typical build-up material with a silicon-based solid fillers and no hollow fillers could have a Dk of around 3.8). Additionally or alternatively, the average Df value in a layer of hollow filler-based build-up material may be less than 0.003 in some instances (e.g., in one embodiment, the Df may be roughly 0.002). The build-up layers of the first outer portion 110A and/or second outer portion 110B may include various hollow filler-based build-up materials with different Dk and/or Df values. For example, a first layer (e.g., adjacent an HSIO layer) may exhibit a lower Dk and/or Df value, while another layer (e.g., that is not adjacent to an HSIO layer) may exhibit a higher Dk and/or Df value. Such embodiments may allow for lower cost manufacturing (e.g., by relaxing process requirements when a lower Dk and/or Df value is not needed) and/or allow for tuning of the system performance (e.g., in some instances, a moderate Dk and/or Df value may help reduce crosstalk for some interconnect lines).

In various examples, the voids of a hollow filler-based build-up material may have a generally spheroid or sphere-like shape, oblong shape, oval shape, rectangular shape, ellipsoid shape, or other suitable shape. In some embodiments, the voids may have diameters ranging from approximately 300 nanometers (nm) to 700 (nm). In some embodiments, the voids may be generally uniform in size (e.g., less than a 10% difference in diameter) across a layer of a hollow filler-based build-up material or may vary in size across the layer of the hollow filler-based build-up material.

In various embodiments, the hollow fillers may be distributed throughout a layer of the hollow filler based material in a relatively uniform manner (e.g., the average density of the hollow fillers may be relatively constant throughout the layer). In other embodiments, the hollow fillers may be distributed unevenly or irregularly (e.g., the hollow filler may have a higher or lower density in one or more particular regions of a layer of the hollow filler based material).

A layer of the hollow filler-based build-up material may be formed in any suitable manner, such as through placement, lamination, molding (e.g., overmolding), dispensing, deposition, or other suitable method. In one method, silicon dioxide is coated or glued on top of a set of organic beads (e.g., having a generally spherical shape). A small opening is maintained (e.g., silicon dioxide growth initiated on the organic template beads is normally porous, so there will be openings for template etching or calcination for removal). A high temperature treatment is then applied, causing the organic material to evaporate. Another layer of the structure is then coated on top of the resulting layer in order to seal the opening. In essence, the organic material operates as a template, and the high temperature removes the area occupied by the template, resulting in the hollow fillers.

In the embodiment depicted, all of the build-up layers comprise hollow fillers. Hollow filler-based build-up material is formed both under and over various interconnect layers (e.g., some of which may be HSIO lines) and the embedded bridge dies 116 and 118. In the embodiment depicted, hollow filler-based build-up material is adjacent to and in contact with at least a portion of the sides of bridge dies 116 and 118 as well as at least a portion of the top surface of the bridge dies 116 and 118. A solder resist layer 136 is formed on the top layer of hollow filler based material and then conductive contacts are formed on top of the solder resist layer 136.

In some instances, a cavity may be formed in a portion of one or more build-up layers comprising hollow filler based material. After formation of conductive contacts 138 in the cavity, a dielectric material 140 (e.g., an underfill material) is formed in the cavity. The embedded bridge die 116 is then embedded within the cavity, then another dielectric layer (which could be a hollow filler based material or other suitable dielectric material) may be formed in the remaining empty space in the cavity.

The package substrate may be coupled to any number of IC dies 124 (e.g., 124A-D), e.g., via a flip chip technique, wire bonding, and/or other suitable couplings. The dies 124 may include any suitable logic. For example, a die 124 may comprise an XPU (such as a central processing unit or other processor), a transceiver, or other suitable logic.

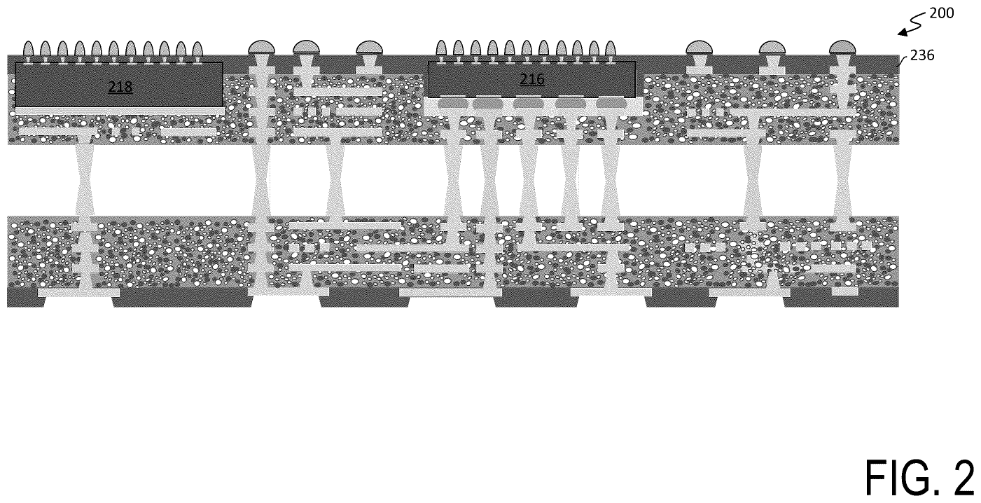

FIG. 2 illustrates a package 200 comprising a package substrate with at least one hollow filler-based build-up material and an embedded bridge die 216 providing power delivery, in accordance with any of the embodiments disclosed herein. Package 200 is depicted without any dies attached to the conductive contacts at the top of the package (e.g., such dies may be attached at a later stage). Any suitable aspects of package 200 may be similar to corresponding aspects of package 100.

In the embodiment of FIG. 2, the top surface of the embedded bridge die 216 (which may have any of the characteristics of embedded bridge die 116) and the top surface of embedded bridge die 218 (which may have any of the characteristics of embedded bride die 118) are not in contact with a hollow filler-based build-up material. Rather, a solder resist layer 236 is formed on top of the embedded bridge dies 216 and 218. As depicted, the solder resist layer 236 may also be in contact with at least a portion of the left and right sides of the embedded bridge dies 216 and 218.

As alluded to above, in addition or as an alternative to a package comprising various build-up layers of hollow filler-based materials with different compositions (and thus different Dk and/or Df values), in some embodiments, the build-up layers of a package may selectively include hollow fillers (e.g., one or more layers include hollow fillers while one or more other layers do not include hollow fillers). Such embodiments may result in cost savings (as build-up layers in which the hollow filler based material is not used may, in some instances, be cheaper to manufacture) and/or reduced process risk.

In some examples, only the layers that are adjacent to HSIO layers include hollow fillers, where an HSIO layer may, in some instances, refer to an interconnect layer (such as 120B) that is a portion of an interconnect that couples a high speed signal between an IC die 124 and a conductive contact 128 of the package 100 (e.g., to be coupled to another electronic device via, e.g., a printed circuit board). In various embodiments, a high speed signal may travel at a high speed relative to other signals communicated by interconnect of the package. For example, a high speed signal may be a signal greater than 10 gigabits per second (Gbps), greater than 100 Gbps, greater than 200 Gbps, etc. In a particular embodiment, an HSIO layer may be a layer that carries a signal that is 224 Gbps or greater. As another example, build-up layers at the top of the package and/or at the bottom of the package may omit the hollow filler based material. As yet another example, build-up layers adjacent to the core may omit the hollow filler based material. As another example, layers in which there are no routing structures (or which are not adjacent to any routing structures) may omit hollow fillers.

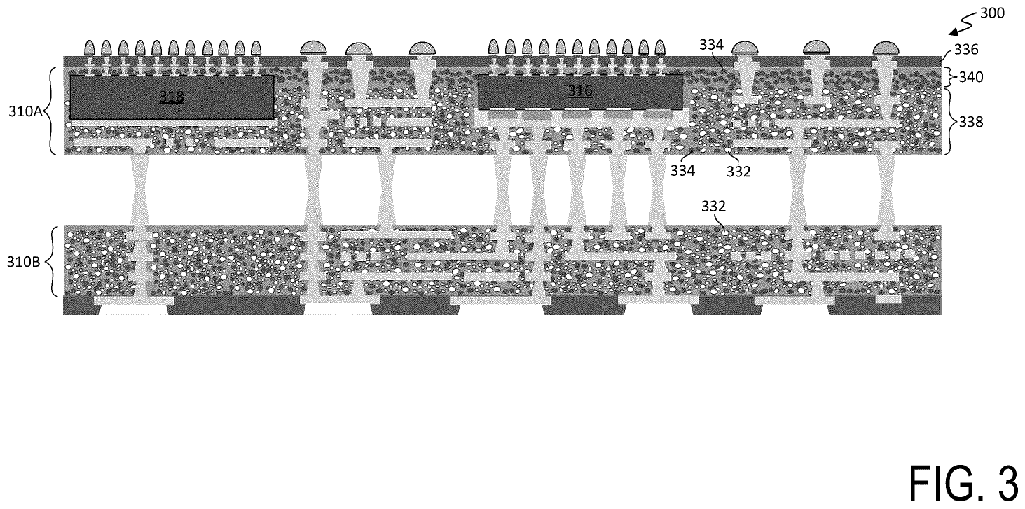

In some instances, layers that omit hollow filler based materials (e.g., in lieu of solid filler-based materials) may be used to achieve a desired flatness (e.g., for reduced bump height variation), viscosity, or topology of a material or for improved encapsulation of embedded components (e.g., embedded bridges). In some examples, the encapsulation layer (e.g., a layer such as 236 or 340 of FIG. 3 that is formed after a bridge die is placed in a cavity of the package that is used to encapsulate the bridge die within the cavity) of the embedded bridge may be a solid filler-based material or other dielectric material and may omit hollow fillers.

FIG. 3 illustrates a package 300 comprising a package substrate with hollow filler-based build-up materials and solid filler-based build-up materials, in accordance with certain embodiments. The package 300 also includes an embedded bridge die 316 providing power delivery through power vias (not explicitly shown) as well as an embedded bridge die 318 that does not include power vias. Package 300 is depicted without any dies attached to the conductive contacts at the top of the package (such dies may be attached at a later stage). Any suitable aspects of package 300 may be similar to aspects of package 100 or package 200.

In the embodiment of FIG. 3, the build-up layers of the first outer layer 310A include a first set 338 of build-up layers that include hollow filler-based build-up materials and a second set 340 of one or more build-up layers that do not include hollow filler-based build-up materials, but rather include a solid filler-based build-up material.

In this embodiment, the one or more build-up layers that do not include hollow fillers 332 are at the top of the package substrate under and/or in contact with a solder resist layer 336. This material may be in contact with at least a portion of the top surfaces of the embedded bridges 316 and 318 and/or the sides of the embedded bridges 316 and 318.

In various embodiments, solid fillers 334 of one or more of the first set 338 of build-up layers may comprise the same material as solid fillers 334 of one or more of the second set 340 of build-up layers (or may comprise a different material).

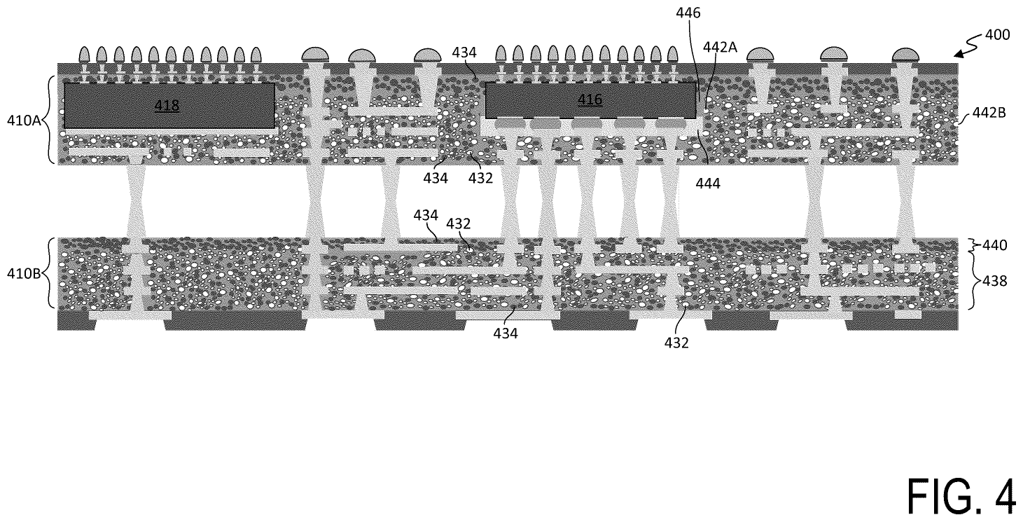

FIG. 4 illustrates a package 400 comprising a package substrate with hollow filler-based build-up materials and solid filler-based build-up materials, in accordance with certain embodiments. The package 400 also includes an embedded bridge die 416 providing power delivery through power vias (not explicitly shown) as well as an embedded bridge die 418 that does not include power vias. Package 400 is depicted without any dies attached to the conductive contacts at the top of the package (such dies may be attached at a later stage). Any suitable aspects of package 400 may be similar to aspects of package 100, package 200, or package 300.

In the embodiment of FIG. 4, the build-up layers of the second outer layer 410B include a first set 438 of build-up layers that include hollow filler-based build-up materials and a second set 440 of one or more build-up layers that do not include hollow filler-based build-up materials, but rather include a solid filler-based build-up material.

In this embodiment, the one or more build-up layers of the second outer layer 410B that do not include hollow fillers 432 are at the top of the second outer layer 410B and under and/or in contact with the core layer 408, while the build-up layers of the second outer layer 410B that include hollow fillers 432 and solid fillers 434 are nearer the bottom of the package 400.

As alluded to above, the void of a hollow filler may have a generally spheroid or sphere-like shape, an ellipsoid or ellipsoid-like shape, or other three dimensional shape with any suitable cross sectional shape (e.g., the hollow filler may have an oblong, oval, rectangular, elliptical, or other suitable cross-section). In some embodiments, singulation, etching, laser removal, or other action performed on a hollow filler-based build-up material may result in formation of truncated hollow fillers 442 (e.g., 442A-B). A truncated hollow filler 442 may be distinguished from other hollow fillers 432 in that a void of a hollow filler 432 may be completely enclosed by a solid material (e.g., resin or other polymer) whereas the void of a truncated hollow filler 442 is only partially enclosed by the solid material (and could either be open to the air or enclosed by some material other than the solid material). Thus, with respect to hollow fillers 432 that have a spherical shape and an outer perimeter of a circle in a cross section (such as that shown in FIG. 4), a corresponding truncated hollow filler 442 would have an outer perimeter that is only a portion of a circle in the cross section. Similarly, for hollow fillers 432 that have an ellipsoid shape and an outer perimeter that is an ellipse in a cross section, a corresponding truncated hollow filler 442 would have an outer perimeter that is only a portion of an ellipse in the cross section. Thus, in some embodiments, a cross section of a truncated hollow filler 442 may include a perimeter of the void that is a partial arc (e.g., of a circle, ellipsis, or other curve), but not a full arc (e.g., is not a circle, ellipse, or other closed curve).

FIG. 4 illustrates various examples of truncated hollow fillers 442. For example, truncated hollow filler 442A is adjacent a side of a cavity that is formed (e.g., via laser) for the embedded bridge die 416. The embedded bridge die 416, a first dielectric material 444, and a second dielectric material 446 (or a single dielectric material or additional dielectric materials) may be placed within the cavity. The truncated hollow filler 442A includes a perimeter that includes a partial oval in a cross section (where a solid material of the first outer layer 410A outside the void of the truncated hollow filler 442A defines the partial oval). The truncated hollow filler 442A is also bounded by the second dielectric material 446 (in some instances, some of the second dielectric material 446 may enter into and fill a portion of the void during formation) and/or the first dielectric material 444. As another example, truncated hollow filler 442B is adjacent an outer side of the package (e.g., that may be formed via singulation of various different packages). The truncated hollow filler 442B includes a perimeter that includes a partial oval in a cross section (where a solid material of the first outer layer 410A outside the void of the truncated hollow filler 442A defines the partial oval). The truncated hollow filler 442B is not further bounded, but is open to the area around the package 400.

Any suitable edges of the package 400 or cavities formed therein may be adjacent to a plurality of truncated hollow fillers.

Where various characteristics are described or illustrated in a particular FIG. for a particular component (e.g., a hollow filler-based build-up material, an outer layer, a core, an embedded bridge, etc.), the various embodiments described herein contemplate that any suitable combination of such characteristics may also apply to the same component as described or illustrated in another FIG.

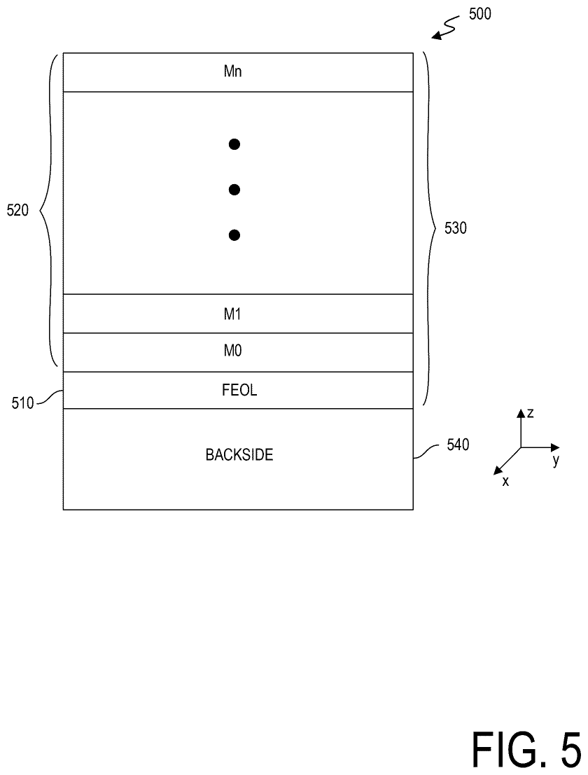

FIG. 5 provides a schematic illustration of a cross-sectional view of an example integrated circuit device (e.g., a chip or die) 500. The IC device 500 may include transistors as well as other circuit elements (e.g., resistors, diodes, capacitors, inductors, etc.). The IC device 500 may represent a die that may be attached to a package substrate in various embodiments.

As shown in FIG. 5, the IC device 500 may include a front side 530 comprising a front-end-of-line (FEOL) 510 that includes various logic layers, circuits, and devices to drive and control a logic IC. These circuits and devices may be configured for any number of functions, such as logic or compute transistors, input/output (I/O) transistors, access or switching transistors, and/or radio frequency (RF) transistors, to name a few examples. According to some embodiments, in addition to these devices and circuits, FEOL 510 may include, for example, one or more other layers or structures associated with the semiconductor devices and circuits. For example, the FEOL can also include a substrate and one or more dielectric layers that surround active and/or conductive portions of the devices and circuits. The FEOL may also include one or more conductive contacts that provide electrical contact to transistor elements such as gate structures, drain regions, or source regions. The FEOL may also include local interconnect (e.g., vias or lines) that connect contacts to interconnect features within a back-end-of-line (BEOL) 520.

The front side 530 of the IC device 500 also includes a BEOL 520 including various metal interconnect layers (e.g., metal 0 through metal n, where n is any suitable integer). Various metal layers of the BEOL 520 may be used to interconnect the various inputs and outputs of the FEOL 510.

Generally speaking, each of the metal layers of the BEOL 520, e.g., each of the layers M0-Mn shown in FIG. 5, may include a via portion and a trench/interconnect portion. Typically, the trench portion of a metal layer is above the via portion, but, in other embodiments, a trench portion may be provided below a via portion of any given metal layer of the BEOL 520. The trench portion of a metal layer may be configured for transferring signals and power along metal lines (also sometimes referred to as “trenches”) extending in the x-y plane (e.g., in the x or y directions), while the via portion of a metal layer may be configured for transferring signals and power through metal vias extending in the z-direction, e.g., to any of the adjacent metal layers above or below. Accordingly, vias connect metal structures (e.g., metal lines or vias) from one metal layer to metal structures of an adjacent metal layer. While referred to as “metal” layers, various layers of the BEOL 520, e.g., layers M0-Mn shown in FIG. 5, may include certain patterns of conductive metals, e.g., copper (Cu) or aluminum (Al), or metal alloys, or more generally, patterns of an electrically conductive material (e.g., including carbon based materials), formed in an insulating medium such as an interlayer dielectric (ILD). The insulating medium may include any suitable ILD materials such as silicon oxide, silicon nitride, aluminum oxide, and/or silicon oxynitride. In various embodiments, any one or more of these layers may additionally include active devices (e.g., transistors, diodes) and/or passive devices (e.g., capacitors, resistors, inductors).

The IC device 500 may also include a backside 540. For example, the backside 540 may formed on the opposite side of a wafer from the front side 530. In various embodiments, the backside 540 may include any suitable elements to assist operation of the IC device 500. For example, the backside 540 may include various metal layers to deliver power to logic of the FEOL 510.

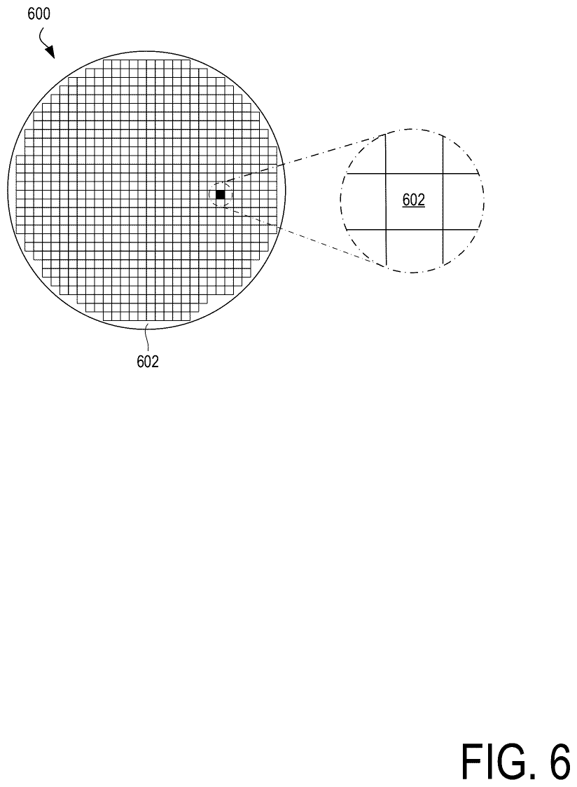

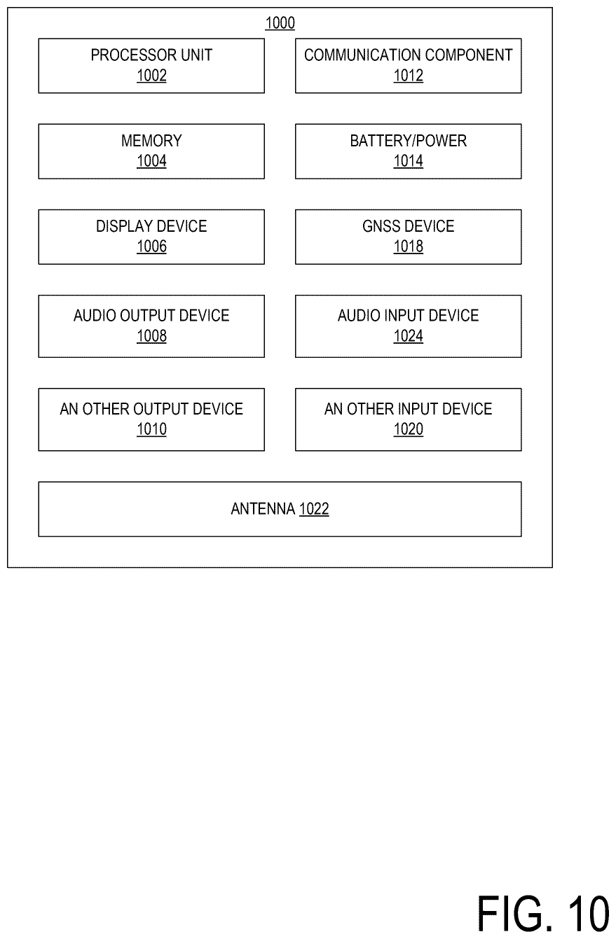

FIG. 6 is a top view of a wafer 600 and dies 602, wherein individual dies may be attached to a package substrate with a hollow filler-based buildup material as disclosed herein. The wafer 600 may be composed of semiconductor material and may include one or more dies 602 having integrated circuit structures formed on a surface of the wafer 600. The individual dies 602 may be a repeating unit of an integrated circuit product that includes any suitable integrated circuit. After the fabrication of the semiconductor product is complete, the wafer 600 may undergo a singulation process in which the dies 602 are separated from one another to provide discrete “chips” of the integrated circuit product. The die 602 may include one or more transistors, supporting circuitry to route electrical signals to the transistors, passive components (e.g., signal traces, resistors, capacitors, or inductors), and/or any other integrated circuit components. In some embodiments, the wafer 600 or the die 602 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 602. For example, a memory array formed by multiple memory devices may be formed on a same die 602 as a processor unit (e.g., the processor unit 1002 of FIG. 10) or other logic that is configured to store information in the memory devices or execute instructions stored in the memory array. In some embodiments, various ones of the microelectronic assemblies disclosed herein may be manufactured using a die-to-wafer assembly technique in which some dies are attached to a wafer 600 that include other dies, and the wafer 600 is subsequently singulated.

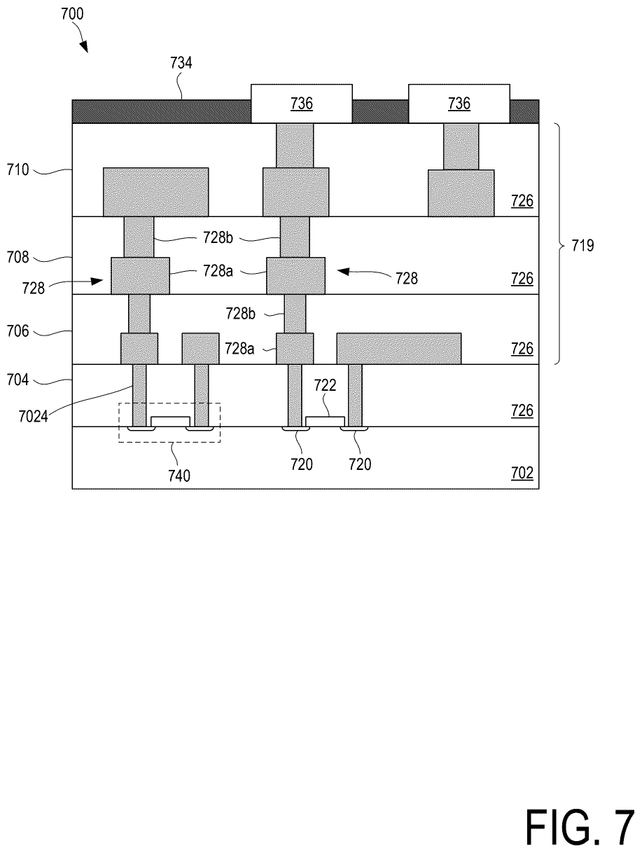

FIG. 7 is a cross-sectional side view of an integrated circuit device 700 that may be attached to a substrate package with a hollow filler-based buildup material as disclosed herein. One or more of the integrated circuit devices 700 may be included in one or more dies 602 (FIG. 6). The integrated circuit device 700 may be formed on a die substrate 702 (e.g., the wafer 600 of FIG. 6) and may be included in a die (e.g., the die 602 of FIG. 6). The die substrate 702 may be a semiconductor substrate composed of semiconductor material systems including, for example, n-type or p-type materials systems (or a combination of both). The die substrate 702 may include, for example, a crystalline substrate formed using a bulk silicon or a silicon-on-insulator (SOI) substructure. In some embodiments, the die substrate 702 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 702. Although a few examples of materials from which the die substrate 702 may be formed are described here, any material that may serve as a foundation for an integrated circuit device 700 may be used. The die substrate 702 may be part of a singulated die (e.g., the dies 602 of FIG. 6) or a wafer (e.g., the wafer 600 of FIG. 6).

The integrated circuit device 700 may include one or more device layers 704 disposed on the die substrate 702. The device layer 704 may include features of one or more transistors 740 (e.g., metal oxide semiconductor field-effect transistors (MOSFETs)) formed on the die substrate 702. The transistors 740 may include, for example, one or more source and/or drain (S/D) regions 720, a gate 722 to control current flow between the S/D regions 720, and one or more S/D contacts 724 to route electrical signals to/from the S/D regions 720. The transistors 740 may include additional features not depicted for the sake of clarity, such as device isolation regions, gate contacts, and the like. The transistors 740 are not limited to the type and configuration depicted in FIG. 7 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

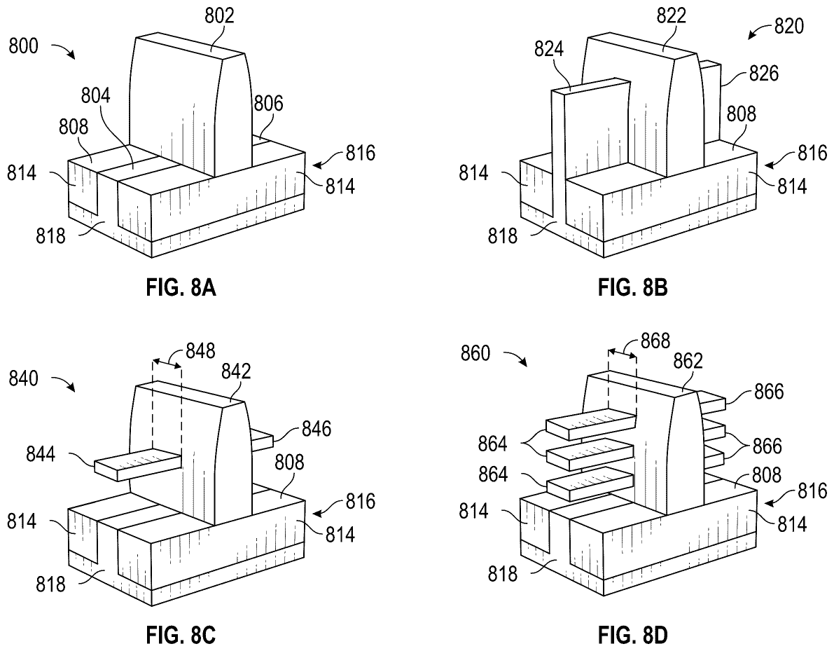

FIGS. 8A-8D are simplified perspective views of example planar, FinFET, gate-all-around, and stacked gate-all-around transistors. The transistors illustrated in FIGS. 8A-8D are formed on a substrate 816 having a surface 808. Isolation regions 814 separate the source and drain regions of the transistors from other transistors and from a bulk region 818 of the substrate 816.

FIG. 8A is a perspective view of an example planar transistor 800 comprising a gate 802 that controls current flow between a source region 804 and a drain region 806. The transistor 800 is planar in that the source region 804 and the drain region 806 are planar with respect to the substrate surface 808.

FIG. 8B is a perspective view of an example FinFET transistor 820 comprising a gate 822 that controls current flow between a source region 824 and a drain region 826. The transistor 820 is non-planar in that the source region 824 and the drain region 826 comprise “fins” that extend upwards from the substrate surface 828. As the gate 822 encompasses three sides of the semiconductor fin that extends from the source region 824 to the drain region 826, the transistor 820 can be considered a tri-gate transistor. FIG. 8B illustrates one S/D fin extending through the gate 822, but multiple S/D fins can extend through the gate of a FinFET transistor.

FIG. 8C is a perspective view of a gate-all-around (GAA) transistor 840 comprising a gate 842 that controls current flow between a source region 844 and a drain region 846. The transistor 840 is non-planar in that the source region 844 and the drain region 846 are elevated from the substrate surface 828.

FIG. 8D is a perspective view of a GAA transistor 860 comprising a gate 862 that controls current flow between multiple elevated source regions 864 and multiple elevated drain regions 866. The transistor 860 is a stacked GAA transistor as the gate controls the flow of current between multiple elevated S/D regions stacked on top of each other. The transistors 840 and 860 are considered gate-all-around transistors as the gates encompass all sides of the semiconductor portions that extends from the source regions to the drain regions. The transistors 840 and 860 can alternatively be referred to as nanowire, nanosheet, or nanoribbon transistors depending on the width (e.g., widths 848 and 868 of transistors 840 and 860, respectively) of the semiconductor portions extending through the gate.

Returning to FIG. 7, a transistor 740 may include a gate 722 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 740 is to be a p-type metal oxide semiconductor (PMOS) or an n-type metal oxide semiconductor (NMOS) transistor. In some implementations, the gate electrode may consist of or comprise a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 740 along the source-channel-drain direction, the gate electrode may consist of or comprise a U-shaped structure that includes a bottom portion substantially parallel to the surface of the die substrate 702 and two sidewall portions that are substantially perpendicular to the top surface of the die substrate 702. In other embodiments, at least one of the metal layers that form the gate electrode may simply be a planar layer that is substantially parallel to the top surface of the die substrate 702 and does not include sidewall portions substantially perpendicular to the top surface of the die substrate 702. In other embodiments, the gate electrode may consist of or comprise a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 720 may be formed within the die substrate 702 adjacent to the gate 722 of individual transistors 740. The S/D regions 720 may be formed using an implantation/diffusion process or an etching/deposition process, for example. In the former process, dopants such as boron, aluminum, antimony, phosphorous, or arsenic may be ion-implanted into the die substrate 702 to form the S/D regions 720. An annealing process that activates the dopants and causes them to diffuse farther into the die substrate 702 may follow the ion-implantation process. In the latter process, the die substrate 702 may first be etched to form recesses at the locations of the S/D regions 720. An epitaxial deposition process may then be carried out to fill the recesses with material that is used to fabricate the S/D regions 720. In some implementations, the S/D regions 720 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 720 may be formed using one or more alternate semiconductor materials such as germanium or a group III-V material or alloy. In further embodiments, one or more layers of metal and/or metal alloys may be used to form the S/D regions 720.

Electrical signals, such as power and/or input/output (I/O) signals, may be routed to and/or from the devices (e.g., transistors 740) of the device layer 704 through one or more interconnect layers disposed on the device layer 704 (illustrated in FIG. 7 as interconnect layers 706-710). For example, electrically conductive features of the device layer 704 (e.g., the gate 722 and the S/D contacts 724) may be electrically coupled with the interconnect structures 728 of the interconnect layers 706-710. The one or more interconnect layers 706-710 may form a metallization stack (also referred to as an “ILD stack”) 719 of the integrated circuit device 700.

The interconnect structures 728 (e.g., lines) may be arranged within the interconnect layers 706-710 to route electrical signals according to a wide variety of designs; in particular, the arrangement is not limited to the particular configuration of interconnect structures 728 depicted in FIG. 7. Although a particular number of interconnect layers 706-710 is depicted in FIG. 7, embodiments of the present disclosure include integrated circuit devices having more or fewer interconnect layers than depicted.

In some embodiments, the interconnect structures 728 may include lines 728a and/or vias 728b filled with an electrically conductive material such as a metal. The lines 728a may be arranged to route electrical signals in a direction of a plane that is substantially parallel with a surface of the die substrate 702 upon which the device layer 704 is formed. For example, the lines 728a may route electrical signals in a direction in and out of the page and/or in a direction across the page. The vias 728b may be arranged to route electrical signals in a direction of a plane that is substantially perpendicular to the surface of the die substrate 702 upon which the device layer 704 is formed. In some embodiments, the vias 728b may electrically couple lines 728a of different interconnect layers 706-710 together.

The interconnect layers 706-710 may include a dielectric material 726 disposed between the interconnect structures 728, as shown in FIG. 7. In some embodiments, dielectric material 726 disposed between the interconnect structures 728 in different ones of the interconnect layers 706-710 may have different compositions; in other embodiments, the composition of the dielectric material 726 between different interconnect layers 706-710 may be the same. The device layer 704 may include a dielectric material 726 disposed between the transistors 740 and a bottom layer of the metallization stack as well. The dielectric material 726 included in the device layer 704 may have a different composition than the dielectric material 726 included in the interconnect layers 706-710; in other embodiments, the composition of the dielectric material 726 in the device layer 704 may be the same as a dielectric material 726 included in any one of the interconnect layers 706-710.

A first interconnect layer 706 (referred to as Metal 1 or “M1”) may be formed directly on the device layer 704. In some embodiments, the first interconnect layer 706 may include lines 728a and/or vias 728b, as shown. The lines 728a of the first interconnect layer 706 may be coupled with contacts (e.g., the S/D contacts 724) of the device layer 704. The vias 728b of the first interconnect layer 706 may be coupled with the lines 728a of a second interconnect layer 708.

The second interconnect layer 708 (referred to as Metal 2 or “M2”) may be formed directly on the first interconnect layer 706. In some embodiments, the second interconnect layer 708 may include via 728b to couple the lines 728 of the second interconnect layer 708 with the lines 728a of a third interconnect layer 710. Although the lines 728a and the vias 728b are structurally delineated with a line within individual interconnect layers for the sake of clarity, the lines 728a and the vias 728b may be structurally and/or materially contiguous (e.g., simultaneously filled during a dual-damascene process) in some embodiments.

The third interconnect layer 710 (referred to as Metal 3 or “M3”) (and additional interconnect layers, as desired) may be formed in succession on the second interconnect layer 708 according to similar techniques and configurations described in connection with the second interconnect layer 708 or the first interconnect layer 706. In some embodiments, the interconnect layers that are “higher up” in the metallization stack 719 in the integrated circuit device 700 (i.e., farther away from the device layer 704) may be thicker that the interconnect layers that are lower in the metallization stack 719, with lines 728a and vias 728b in the higher interconnect layers being thicker than those in the lower interconnect layers.

The integrated circuit device 700 may include a solder resist material 734 (e.g., polyimide or similar material) and one or more conductive contacts 736 formed on the interconnect layers 706-710. In FIG. 7, the conductive contacts 736 are illustrated as taking the form of bond pads. The conductive contacts 736 may be electrically coupled with the interconnect structures 728 and configured to route the electrical signals of the transistor(s) 740 to external devices. For example, solder bonds may be formed on the one or more conductive contacts 736 to mechanically and/or electrically couple an integrated circuit die including the integrated circuit device 700 with another component (e.g., a printed circuit board). The integrated circuit device 700 may include additional or alternate structures to route the electrical signals from the interconnect layers 706-710; for example, the conductive contacts 736 may include other analogous features (e.g., posts) that route the electrical signals to external components.

In some embodiments in which the integrated circuit device 700 is a double-sided die, the integrated circuit device 700 may include another metallization stack (not shown) on the opposite side of the device layer(s) 704. This metallization stack may include multiple interconnect layers as discussed above with reference to the interconnect layers 706-710, to provide conductive pathways (e.g., including conductive lines and vias) between the device layer(s) 704 and additional conductive contacts (not shown) on the opposite side of the integrated circuit device 700 from the conductive contacts 736.

In other embodiments in which the integrated circuit device 700 is a double-sided die, the integrated circuit device 700 may include one or more through silicon vias (TSVs) through the die substrate 702; these TSVs may make contact with the device layer(s) 704, and may provide conductive pathways between the device layer(s) 704 and additional conductive contacts (not shown) on the opposite side of the integrated circuit device 700 from the conductive contacts 736. In some embodiments, TSVs extending through the substrate can be used for routing power and ground signals from conductive contacts on the opposite side of the integrated circuit device 700 from the conductive contacts 736 to the transistors 740 and any other components integrated into the integrated circuit device (e.g., die) 700, and the metallization stack 719 can be used to route I/O signals from the conductive contacts 736 to transistors 740 and any other components integrated into the integrated circuit device (e.g., die) 700.

Multiple integrated circuit devices 700 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

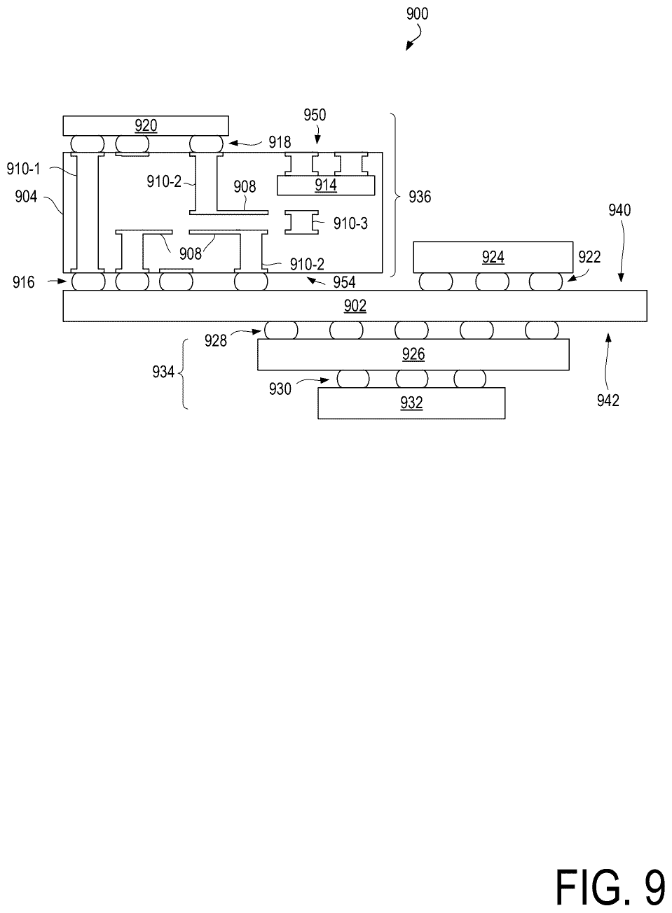

FIG. 9 is a cross-sectional side view of an integrated circuit device assembly 900 that may include a substrate package with a hollow filler-based buildup material as disclosed herein. In some embodiments, the integrated circuit device assembly 900 may be a microelectronic assembly. The integrated circuit device assembly 900 includes a number of components disposed on a circuit board 902 (which may be a motherboard, system board, mainboard, etc.). The integrated circuit device assembly 900 includes components disposed on a first face 940 of the circuit board 902 and an opposing second face 942 of the circuit board 902; generally, components may be disposed on one or both faces 940 and 942.

In some embodiments, the circuit board 902 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 902. In other embodiments, the circuit board 902 may be a non-PCB substrate. The integrated circuit device assembly 900 illustrated in FIG. 9 includes a package-on-interposer structure 936 coupled to the first face 940 of the circuit board 902 by coupling components 916. The coupling components 916 may electrically and mechanically couple the package-on-interposer structure 936 to the circuit board 902, and may include solder balls (as shown in FIG. 9), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 936 may include an integrated circuit component 920 coupled to an interposer 904 by coupling components 918. The coupling components 918 may take any suitable form for the application, such as the forms discussed above with reference to the coupling components 916. Although a single integrated circuit component 920 is shown in FIG. 9, multiple integrated circuit components may be coupled to the interposer 904; indeed, additional interposers may be coupled to the interposer 904. The interposer 904 may provide an intervening substrate used to bridge the circuit board 902 and the integrated circuit component 920.

The integrated circuit component 920 may be a packaged or unpackaged integrated circuit product that includes one or more integrated circuit dies (e.g., the die 602 of FIG. 6, the integrated circuit device 700 of FIG. 7) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 920, a single monolithic integrated circuit die comprises solder bumps attached to contacts on the die. The solder bumps allow the die to be directly attached to the interposer 904. The integrated circuit component 920 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 920 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 920 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 920 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 904 may spread connections to a wider pitch or reroute a connection to a different connection. For example, the interposer 904 may couple the integrated circuit component 920 to a set of ball grid array (BGA) conductive contacts of the coupling components 916 for coupling to the circuit board 902. In the embodiment illustrated in FIG. 9, the integrated circuit component 920 and the circuit board 902 are attached to opposing sides of the interposer 904; in other embodiments, the integrated circuit component 920 and the circuit board 902 may be attached to a same side of the interposer 904. In some embodiments, three or more components may be interconnected by way of the interposer 904.

In some embodiments, the interposer 904 may be formed as a PCB, including multiple metal layers separated from one another by layers of dielectric material and interconnected by electrically conductive vias. In some embodiments, the interposer 904 may be formed of an epoxy resin, a fiberglass-reinforced epoxy resin, an epoxy resin with inorganic fillers, a ceramic material, or a polymer material such as polyimide. In some embodiments, the interposer 904 may be formed of alternate rigid or flexible materials that may include the same materials described above for use in a semiconductor substrate, such as silicon, germanium, and other group III-V and group IV materials. The interposer 904 may include metal interconnects 908 and vias 910, including but not limited to through hole vias 910-1 (that extend from a first face 950 of the interposer 904 to a second face 954 of the interposer 904), blind vias 910-2 (that extend from the first or second faces 950 or 954 of the interposer 904 to an internal metal layer), and buried vias 910-3 (that connect internal metal layers).

In some embodiments, the interposer 904 can comprise a silicon interposer. Through silicon vias (TSV) extending through the silicon interposer can connect connections on a first face of a silicon interposer to an opposing second face of the silicon interposer. In some embodiments, an interposer 904 comprising a silicon interposer can further comprise one or more routing layers to route connections on a first face of the interposer 904 to an opposing second face of the interposer 904.

The interposer 904 may further include embedded devices 914, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 904. The package-on-interposer structure 936 may take the form of any of the package-on-interposer structures known in the art.

The integrated circuit device assembly 900 may include an integrated circuit component 924 coupled to the first face 940 of the circuit board 902 by coupling components 922. The coupling components 922 may take the form of any of the embodiments discussed above with reference to the coupling components 916, and the integrated circuit component 924 may take the form of any of the embodiments discussed above with reference to the integrated circuit component 920.

The integrated circuit device assembly 900 illustrated in FIG. 9 includes a package-on-package structure 934 coupled to the second face 942 of the circuit board 902 by coupling components 928. The package-on-package structure 934 may include an integrated circuit component 926 and an integrated circuit component 932 coupled together by coupling components 930 such that the integrated circuit component 926 is disposed between the circuit board 902 and the integrated circuit component 932. The coupling components 928 and 930 may take the form of any of the embodiments of the coupling components 916 discussed above, and the integrated circuit components 926 and 932 may take the form of any of the embodiments of the integrated circuit component 920 discussed above. The package-on-package structure 934 may be configured in accordance with any of the package-on-package structures known in the art.

FIG. 10 is a block diagram of an example electrical device 1000 that may include a substrate package with a hollow filler-based buildup material as disclosed herein. For example, any suitable components of the electrical device 1000 may include one or more of the integrated circuit device assemblies 900, integrated circuit components 920, integrated circuit devices 700, integrated circuit dies 602, or other components disclosed herein. A number of components are illustrated in FIG. 10 as included in the electrical device 1000, but any one or more of these components may be omitted or duplicated, as suitable for the application. In some embodiments, some or all of the components included in the electrical device 1000 may be attached to one or more motherboards mainboards, or system boards. In some embodiments, one or more of these components are fabricated onto a single system-on-a-chip (SoC) die.

Additionally, in various embodiments, the electrical device 1000 may not include one or more of the components illustrated in FIG. 10, but the electrical device 1000 may include interface circuitry for coupling to the one or more components. For example, the electrical device 1000 may not include a display device 1006, but may include display device interface circuitry (e.g., a connector and driver circuitry) to which a display device 1006 may be coupled. In another set of examples, the electrical device 1000 may not include an audio input device 1024 or an audio output device 1008, but may include audio input or output device interface circuitry (e.g., connectors and supporting circuitry) to which an audio input device 1024 or audio output device 1008 may be coupled.

The electrical device 1000 may include one or more processor units 1002 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1002 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1000 may include a memory 1004, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1004 may include memory that is located on the same integrated circuit die as the processor unit 1002. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1000 can comprise one or more processor units 1002 that are heterogeneous or asymmetric to another processor unit 1002 in the electrical device 1000. There can be a variety of differences between the processing units 1002 in a system in terms of a spectrum of metrics of merit including architectural, microarchitectural, thermal, power consumption characteristics, and the like. These differences can effectively manifest themselves as asymmetry and heterogeneity among the processor units 1002 in the electrical device 1000.

In some embodiments, the electrical device 1000 may include a communication component 1012 (e.g., one or more communication components). For example, the communication component 1012 can manage wireless communications for the transfer of data to and from the electrical device 1000. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1012 may operate in accordance with other wireless protocols in other embodiments. The electrical device 1000 may include an antenna 1022 to facilitate wireless communications and/or to receive other wireless communications (such as amplitude modulation (AM) or frequency modulation (FM) radio transmissions).

In some embodiments, the communication component 1012 may manage wired communications, such as electrical, optical, or any other suitable communication protocols (e.g., IEEE 802.3 Ethernet standards). As noted above, the communication component 1012 may include multiple communication components. For instance, a first communication component 1012 may be dedicated to shorter-range wireless communications such as Wi-Fi or Bluetooth, and a second communication component 1012 may be dedicated to longer-range wireless communications such as global positioning system (GPS), EDGE, GPRS, CDMA, WiMAX, LTE, EV-DO, or others. In some embodiments, a first communication component 1012 may be dedicated to wireless communications, and a second communication component 1012 may be dedicated to wired communications.

The electrical device 1000 may include battery/power circuitry 1014. The battery/power circuitry 1014 may include one or more energy storage devices (e.g., batteries or capacitors) and/or circuitry for coupling components of the electrical device 1000 to an energy source separate from the electrical device 1000 (e.g., AC line power).

The electrical device 1000 may include a display device 1006 (or corresponding interface circuitry, as discussed above). The display device 1006 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1000 may include an audio output device 1008 (or corresponding interface circuitry, as discussed above). The audio output device 1008 may include any embedded or wired or wirelessly connected external device that generates an audible indicator, such speakers, headsets, or earbuds.

The electrical device 1000 may include an audio input device 1024 (or corresponding interface circuitry, as discussed above). The audio input device 1024 may include any embedded or wired or wirelessly connected device that generates a signal representative of a sound, such as microphones, microphone arrays, or digital instruments (e.g., instruments having a musical instrument digital interface (MIDI) output). The electrical device 1000 may include a Global Navigation Satellite System (GNSS) device 1018 (or corresponding interface circuitry, as discussed above), such as a Global Positioning System (GPS) device. The GNSS device 1018 may be in communication with a satellite-based system and may determine a geolocation of the electrical device 1000 based on information received from one or more GNSS satellites, as known in the art.

The electrical device 1000 may include an other output device 1010 (or corresponding interface circuitry, as discussed above). Examples of the other output device 1010 may include an audio codec, a video codec, a printer, a wired or wireless transmitter for providing information to other devices, or an additional storage device.

The electrical device 1000 may include an other input device 1020 (or corresponding interface circuitry, as discussed above). Examples of the other input device 1020 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1000 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1000 may be any other electronic device that processes data. In some embodiments, the electrical device 1000 may comprise multiple discrete physical components. Given the range of devices that the electrical device 1000 can be manifested as in various embodiments, in some embodiments, the electrical device 1000 can be referred to as a computing device or a computing system.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

It will also be understood that, although the terms “first,” “second,” and so forth may be used herein to describe various elements, these elements should not be limited by these terms. These terms are only used to distinguish one element from another, and are not intended to imply that the objects so described must be in a given sequence, either temporally, spatially, in ranking or in any other manner. For example, a first contact could be termed a second contact, and, similarly, a second contact could be termed a first contact, without departing from the scope of the present example embodiments. The first contact and the second contact are both contacts, but they are not the same contact.

As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. For example, the phrase “A and/or B” means (A), (B), or (A and B), while the phrase “A, B, and/or C” means (A), (B), (C), (A and B), (A and C), (B and C), or (A, B, and C).

As used throughout this description, and in the claims, a list of items joined by the term “at least one of” or “one or more of” can mean any combination of the listed terms.

It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Furthermore, the terms “comprising,” “including,” “having,” and the like, as used with respect to embodiments of the present disclosure, are synonymous.

The description may use the phrases “in an embodiment,” “according to some embodiments,” “in accordance with embodiments,” or “in embodiments,” which may each refer to one or more of the same or different embodiments.

As used herein, the term “module” refers to being part of, or including an ASIC, an electronic circuit, a system on a chip, a processor (shared, dedicated, or group), a solid state device, a memory (shared, dedicated, or group) that execute one or more software or firmware programs, a combinational logic circuit, and/or other suitable components that provide the described functionality.

As used herein, “electrically conductive” in some examples may refer to a property of a material having an electrical conductivity greater than or equal to 10⁷ Siemens per meter (S/m) at 20 degrees Celsius. Examples of such materials include Cu, Ag, Al, Au, W, Zn and Ni.

The term “signal” may refer to at least one current signal, voltage signal, magnetic signal, or data/clock signal.

Throughout the specification, and in the claims, the term “connected” means a direct connection, such as electrical, mechanical, or magnetic connection between the elements that are connected, without any intermediary devices. The term “coupled” means a direct or indirect connection, such as a direct electrical, mechanical, or magnetic connection between the elements that are connected or an indirect connection, through one or more passive or active intermediary devices.

The description may use perspective-based descriptions such as top/bottom, in/out, over/under, and the like. Such descriptions are merely used to facilitate the discussion and are not intended to restrict the application of embodiments described herein to any particular orientation.

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer means that at least a part of the first material or layer is in direct physical contact with at least a part of that second material/layer. Similar distinctions are to be made in the context of component assemblies.

As used herein, “A is proximate to B” may mean that A is adjacent to B or A is otherwise near to B.

Unless otherwise specified in the specific context of use, the term “predominantly” means more than 50%, or more than half. For example, a composition that is predominantly a first constituent means more than half of the composition (e.g., by volume) is the first constituent (e.g., >50 at. %). The term “primarily” means the most, or greatest, part. For example, a composition that is primarily a first constituent means the composition has more of the first constituent (e.g., by volume) than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

The terms “substantially,” “close,” “approximately,” “near,” and “about,” generally refer to being within +/−10% of a target value (unless specifically specified).

Unless otherwise specified in the explicit context of their use, the terms “substantially equal,” “about equal” or “approximately equal” mean that there is no more than incidental variation between two things so described. In the art, such variation is typically no more than +/−10% of a predetermined target value.

In the corresponding drawings of the embodiments, signals, currents, electrical biases, or magnetic or electrical polarities may be represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, polarity, current, voltage, etc., as dictated by design needs or preferences, may actually comprise one or more signals that may travel in either direction and may be implemented with any suitable type of signal scheme.

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements.

Although the figures may illustrate embodiments where structures are substantially aligned to Cartesian axes (e.g., device structures having substantially vertical sidewalls), positive and negative (re-entrant) sloped feature sidewalls often occur in practice. For example, manufacturing non-idealities may cause one or more structural features to have sloped sidewalls. Thus, attributes illustrated are idealized merely for the sake of clearly describing salient features. It is to be understood that schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 includes an apparatus comprising an integrated circuit package comprising a package substrate comprising an interconnect layer; and at least one dielectric material comprising hollow fillers, the at least one dielectric material in contact with at least a portion of a top side of the interconnect layer and at least a portion of a bottom side of the interconnect layer.

Example 2 includes the subject matter of Example 1, and wherein the integrated circuit package further comprises a bridge die embedded in the package substrate, the bridge die to couple a signal of a first integrated circuit die to a signal of a second integrated circuit die, the bridge die comprising at least one via to carry a power signal for the first integrated circuit die.

Example 3 includes the subject matter of any of Examples 1 and 2, and wherein the at least one dielectric material comprising hollow fillers is in contact with at least a portion of a side of the bridge die.

Example 4 includes the subject matter of any of Examples 1-3, and wherein the at least one dielectric material comprising hollow fillers is in contact with at least a portion of a top surface of the bridge die.

Example 5 includes the subject matter of any of Examples 1-4, and wherein the integrated circuit package further comprises a second bridge die embedded in the package substrate, the second bridge die to couple a signal of a third integrated circuit die to a signal of a fourth integrated circuit die, wherein the second bridge die does not carry a power signal for the third integrated circuit die or the fourth integrated circuit die.

Example 6 includes the subject matter of any of Examples 1-5, and wherein the interconnect layer is to communicate a high speed signal between a first conductive contact of a top side of the integrated circuit package and a second conductive contact of a bottom side of the integrated circuit package.

Example 7 includes the subject matter of any of Examples 1-6, and wherein the at least one dielectric material further comprises solid fillers.

Example 8 includes the subject matter of any of Examples 1-7, and wherein the package substrate further comprises a plurality of build-up layers over a core layer, the plurality of build-up layers comprising the at least one dielectric material comprising hollow fillers.

Example 9 includes the subject matter of any of Examples 1-8, and wherein the plurality of build-up layers further comprise at least one dielectric material that does not include hollow fillers.

Example 10 includes the subject matter of any of Examples 1-9, and wherein the at least one dielectric material is in contact with a solder resist layer of the integrated circuit package.

Example 11 includes the subject matter of any of Examples 1-10, and further including an integrated circuit device coupled to the package substrate.

Example 12 includes the subject matter of any of Examples 1-11, further comprising a printed circuit board coupled to the package substrate.

Example 13 includes an integrated circuit package comprising a core layer; a first plurality of build-up layers above the core layer; a second plurality of build-up layers below the core layer; and a bridge die embedded within the first plurality of build-up layers; wherein the first plurality of build-up layers comprise at least one material comprising hollow fillers.

Example 14 includes the subject matter of Example 13, and wherein the second plurality of build-up layers comprise at least one material comprising hollow fillers.

Example 15 includes the subject matter of any of Examples 13 and 14, and wherein the first plurality of build-up layers comprise at least one dielectric material comprising solid fillers.

Example 16 includes the subject matter of any of Examples 13-15, and wherein the at least one material comprising solid fillers does not include hollow fillers.

Example 17 includes the subject matter of any of Examples 13-16, and wherein the bridge die is to couple a signal of a first integrated circuit die to a signal of a second integrated circuit die, the bridge die comprising at least one via to carry a power signal for the first integrated circuit die.

Example 18 includes the subject matter of any of Examples 13-17, and wherein the at least one material comprising hollow fillers is in contact with at least a portion of a side of the bridge die.

Example 19 includes the subject matter of any of Examples 13-18, and wherein the at least one material comprising hollow fillers is in contact with at least a portion of a top surface of the bridge die.

Example 20 includes the subject matter of any of Examples 13-19, and wherein the integrated circuit package further comprises a second bridge die embedded within the first plurality of build-up layers, the second bridge die to couple a signal of a third integrated circuit die to a signal of a fourth integrated circuit die, wherein the second bridge die does not carry a power signal for the third integrated circuit die or the fourth integrated circuit die.

Example 21 includes the subject matter of any of Examples 13-20, and further including an interconnect layer embedded in the at least one material comprising hollow fillers, wherein the interconnect layer is to communicate a high speed signal between a first conductive contact of a top side of the integrated circuit package and a second conductive contact of a bottom side of the integrated circuit package.

Example 22 includes the subject matter of any of Examples 13-21, and wherein the at least one material further comprises solid fillers.

Example 23 includes the subject matter of any of Examples 13-22, and wherein the first plurality of build-up layers further comprise at least one dielectric material that does not include hollow fillers.

Example 24 includes the subject matter of any of Examples 13-23, and wherein the at least one material is in contact with a solder resist layer of the integrated circuit package.

Example 25 includes the subject matter of any of Examples 13-24, and further including an integrated circuit device.

Example 26 includes the subject matter of any of Examples 13-25, and further including a printed circuit board coupled to the integrated circuit package.

Example 27 includes a system comprising a package substrate comprising a core layer; a plurality of build-up layers above the core layer, the plurality of build-up layers comprising at least one dielectric material comprising hollow fillers; an interconnect layer; and a bridge die embedded within the package substrate, the bridge die to electrically couple a first integrated circuit die to a second integrated circuit die; wherein the at least one dielectric material at least partially surrounds the interconnect layer and the bridge die.

Example 28 includes the subject matter of Example 27, comprising a processor coupled to the package substrate.

Example 29 includes the subject matter of any of Examples 27 and 28, and further including at least one of a network interface, battery, or memory coupled to the processor.

Example 30 includes the subject matter of any of Examples 27-29, and further including a printed circuit board coupled to the package substrate.

Example 31 includes the subject matter of any of Examples 27-30, the bridge die to couple a signal of a first integrated circuit die to a signal of a second integrated circuit die, the bridge die comprising at least one via to carry a power signal for the first integrated circuit die.

Example 32 includes the subject matter of any of Examples 27-31, and wherein the at least one dielectric material comprising hollow fillers is in contact with at least a portion of a side of the bridge die.

Example 33 includes the subject matter of any of Examples 27-32, and wherein the at least one dielectric material comprising hollow fillers is in contact with at least a portion of a top surface of the bridge die.

Example 34 includes the subject matter of any of Examples 27-33, and further including a second bridge die embedded in the package substrate, the second bridge die to couple a signal of a third integrated circuit die to a signal of a fourth integrated circuit die, wherein the second bridge die does not carry a power signal for the third integrated circuit die or the fourth integrated circuit die.

Example 35 includes the subject matter of any of Examples 27-34, and wherein the interconnect layer is to communicate a high speed signal between a first conductive contact of a top side of the package substrate and a second conductive contact of a bottom side of the package substrate.

Example 36 includes the subject matter of any of Examples 27-35, and wherein the at least one dielectric material further comprises solid fillers.

Example 37 includes the subject matter of any of Examples 27-36, and wherein the plurality of build-up layers further comprise at least one dielectric material that does not include hollow fillers.

Example 38 includes the subject matter of any of Examples 27-37, and wherein the at least one dielectric material is in contact with a solder resist layer of the package substrate.

Example 39 includes the subject matter of any of Examples 27-38, and further including an integrated circuit device coupled to the package substrate.

Example 40 includes the subject matter of any of Examples 27-39, and further including a printed circuit board coupled to the package substrate.

Example 41 includes the subject matter of any of Examples 1-12, wherein a first hollow filler of the hollow fillers is adjacent to an edge of the package substrate and is only partially enclosed by a solid material of the at least one dielectric material.

Example 42 includes the subject matter of any of Examples 1-12 or 41, wherein an edge of the integrated circuit package is adjacent to a plurality of hollow fillers with perimeters of partial arcs in a cross section of the integrated circuit package.

Example 43 includes the subject matter of any of Examples 13-26, wherein a first hollow filler of the hollow fillers is adjacent to an edge of the first plurality of build-up layers and is only partially enclosed by a solid material of the at least one dielectric material.

Example 44 includes the subject matter of any of Examples 13-26 or 43, wherein an edge of the first plurality of build-up layers is adjacent to a plurality of hollow fillers with perimeters of partial arcs in a cross section of the first plurality of build-up layers.

Example 45 includes the subject matter of any of Examples 27-40, wherein a first hollow filler of the hollow fillers is adjacent to an edge of the package substrate and is only partially enclosed by a solid material of the at least one dielectric material.

Example 46 includes the subject matter of any of Examples 27-40 or 45, wherein an edge of the package substrate is adjacent to a plurality of hollow fillers with perimeters of partial arcs in a cross section of the integrated circuit package.

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

1. An apparatus comprising:
an integrated circuit package comprising:
a package substrate comprising:
an interconnect layer; and
at least one dielectric material comprising hollow fillers, the at least one dielectric material in contact with at least a portion of a top side of the interconnect layer and at least a portion of a bottom side of the interconnect layer.

2. The apparatus of claim 1, wherein the integrated circuit package further comprises a bridge die embedded in the package substrate, the bridge die to couple a signal of a first integrated circuit die to a signal of a second integrated circuit die, the bridge die comprising at least one via to carry a power signal for the first integrated circuit die.

3. The apparatus of claim 2, wherein the at least one dielectric material comprising hollow fillers is in contact with at least a portion of a side of the bridge die or at least a portion of a top surface of the bridge die.

4. The apparatus of claim 2, wherein the integrated circuit package further comprises a second bridge die embedded in the package substrate, the second bridge die to couple a signal of a third integrated circuit die to a signal of a fourth integrated circuit die, wherein the second bridge die does not carry a power signal for the third integrated circuit die or the fourth integrated circuit die.

5. The apparatus of claim 1, wherein a first hollow filler of the hollow fillers is adjacent to an edge of the package substrate and is only partially enclosed by a solid material of the at least one dielectric material.

6. The apparatus of claim 1, wherein an edge of the integrated circuit package is adjacent to a plurality of hollow fillers with perimeters of partial arcs in a cross section of the integrated circuit package.

7. The apparatus of claim 1, wherein the interconnect layer is to communicate a high speed signal between a first conductive contact of a top side of the integrated circuit package and a second conductive contact of a bottom side of the integrated circuit package.

8. The apparatus of claim 1, wherein the at least one dielectric material further comprises solid fillers.

9. The apparatus of claim 1, wherein the package substrate further comprises a plurality of build-up layers over a core layer, the plurality of build-up layers comprising the at least one dielectric material comprising hollow fillers, wherein the plurality of build-up layers further comprise at least one dielectric material that does not include hollow fillers.

10. The apparatus of claim 1, wherein the at least one dielectric material is in contact with a solder resist layer of the integrated circuit package.

11. The apparatus of claim 1, further comprising an integrated circuit device coupled to the package substrate.

12. The apparatus of claim 11, further comprising a printed circuit board coupled to the package substrate.

13. An integrated circuit package comprising:
a core layer;
a first plurality of build-up layers above the core layer;
a second plurality of build-up layers below the core layer; and
a bridge die embedded within the first plurality of build-up layers;
wherein the first plurality of build-up layers comprise at least one material comprising hollow fillers.

14. The integrated circuit package of claim 13, wherein the second plurality of build-up layers comprise at least one material comprising hollow fillers.

15. The integrated circuit package of claim 13, wherein the first plurality of build-up layers comprise at least one dielectric material comprising solid fillers.

16. The integrated circuit package of claim 13, wherein the at least one material comprising solid fillers does not include hollow fillers.

17. A system comprising:
a package substrate comprising:
a core layer;
a plurality of build-up layers above the core layer, the plurality of build-up layers comprising at least one dielectric material comprising hollow fillers;
an interconnect layer; and
a bridge die embedded within the package substrate, the bridge die to electrically couple a first integrated circuit die to a second integrated circuit die;
wherein the at least one dielectric material at least partially surrounds the interconnect layer and the bridge die.

18. The system of claim 17, comprising a processor coupled to the package substrate.

19. The system of claim 18, further comprising at least one of a network interface, battery, or memory coupled to the processor.

20. The system of claim 19, further comprising a printed circuit board coupled to the package substrate.
